(19) United States
(12) Patent Application Publication
(10) Pub. No.: US 2009/0097296 A1
(43) Pub. Date: Apr. 16, 2009

(54) REDUCED SIZE SEMICONDUCTOR MEMORY DEVICE

(76) Inventor: Khil Ohk KANG, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/123,597

(22) Filed: May 20, 2008

(30) Foreign Application Priority Data
Oct. 16, 2007 (KR) 10-2007-0103879

(51) Int. Cl. G11C 5/02; G11C 8/00

(52) U.S. Cl. 365/51; 365/230.03

(57) ABSTRACT

A semiconductor memory device is described that includes memory banks having memory cells and are laid out as a matrix on a semiconductor chip body. The semiconductor memory device includes a first pad group having first pads that are arranged in a line between two adjoining memory banks and a second pad group having second pads that are also arranged in a line between the two adjoining memory banks parallel to the first pad group. At least one third pad group is also formed interposed between the first and second pad groups having at least one third pad allowing for a reduction in size of the semiconductor memory device.

### CROSS-REFERENCE TO RELATED APPLICATIONS

The present application claims priority to Korean patent application number 10-2007-0103879 filed on Oct. 16, 2007, which is incorporated herein by reference in its entirety.

### BACKGROUND OF THE INVENTION

The present invention relates to a semiconductor memory device, and more particularly, to a semiconductor memory device having a pad arrangement to allow the size of the semiconductor memory device to be decreased.

Currently, technologies for manufacturing a semiconductor device that include a semiconductor memory device suitable for storing data, have been disclosed in the conventional art allowing for large amounts of data to be stored in a semiconductor chip having a small size.

A semiconductor memory device includes memory banks, which have a plurality of semiconductor memory cells for storing a large amount of data, and a plurality of pads that are located around the memory banks. External commands, addresses, data and power are inputted to the plurality of pads that are located around the memory banks.

Recently, as semiconductor device manufacturing technologies improves, the size of the memory banks of a semiconductor memory device has gradually decreased. However, the distance between the pads of the semiconductor memory device has not decreased and it is therefore difficult to continually decrease the size of a semiconductor memory device although the size of the memory banks is decreasing.

The distance between the pads of a semiconductor memory device is determined based upon the diameter of and the distance between test probes that are employed during a testing process to detect defects and to test the performance of the semiconductor memory device.

It is difficult to decrease the diameter of and the distance between the test probes below a predetermined diameter and distance and therefore, it is also difficult to decrease the distance between the pads of a semiconductor memory device. Accordingly, it is difficult to decrease the size of the semiconductor memory device.

### SUMMARY OF THE INVENTION

Embodiments of the present invention are directed to a semiconductor memory device in which the arrangement of pads is modified so that the size of the semiconductor memory device can be decreased.

In one aspect, a semiconductor memory device comprises memory banks including memory cells and located in the shape of a matrix; a first pad group having first pads which are arranged in line between two adjoining memory banks; a second pad group having second pads which are arranged in line between the two adjoining memory banks to be parallel to the first pad group; and at least one third pad group interposed between the first and second pad groups and having at least one third pad.

The memory banks includes a first memory bank, a second memory bank which is located adjacent to the first memory bank, a third memory bank which is located diagonally with respect to the second memory bank, and a fourth memory bank which is located diagonally with respect to the first memory bank.

The first and second pad groups are interposed between the first and third memory banks and between the second and fourth memory banks.

The third pad is interposed between the first and third memory banks and between the second and fourth memory banks.

The first pads and the second pads are arranged to the same number.

A plurality of third pads are located between the first and second pad groups in the shape of a matrix.

The third pads are located in line in a direction which is different from a pad arrangement direction of the first and second pad groups.

The third pads are arranged in a direction which is perpendicular to the pad arrangement direction of the first and second pad groups.

The third pads are arranged in a direction which is oblique to the pad arrangement direction of the first and second pad groups.

### BRIEF DESCRIPTION OF THE DRAWINGS

FIG. 1 is a plan view illustrating a semiconductor memory device in accordance with a first embodiment of the present invention.

FIG. 2 is a plan view illustrating a semiconductor memory device in accordance with a second embodiment of the present invention.

FIG. 3 is a plan view illustrating a state in which the pads is included in the third pad group shown in FIG. 2 are obliquely located.

### DESCRIPTION OF SPECIFIC EMBODIMENTS

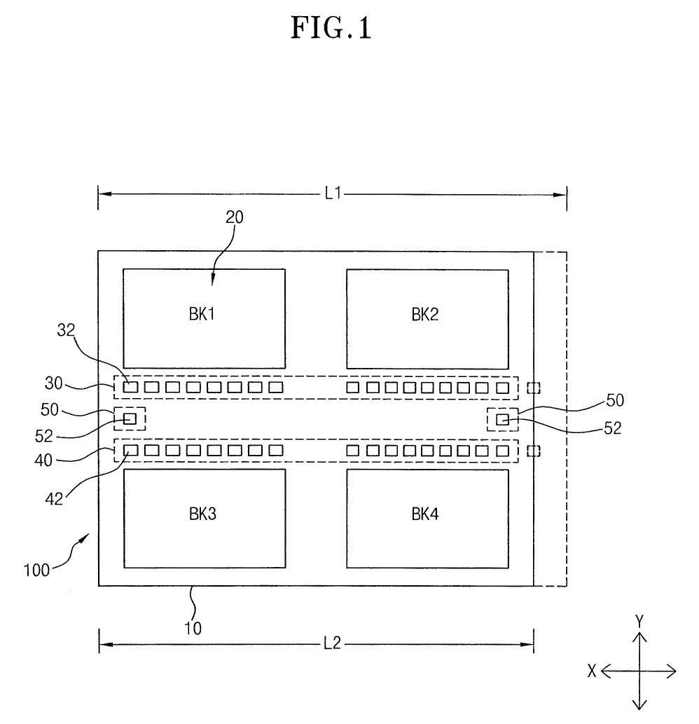

FIG. 1 is a plan view illustrating a semiconductor memory device in accordance with a first embodiment of the present invention.

Referring to FIG. 1, a semiconductor memory device 100 includes a semiconductor chip body 10, at least two memory banks 20, a first pad group 30, a second pad group 40, and third pad groups 50.

In the present embodiment, the semiconductor chip body 10 has, for example, the shape of a rectangular hexahedron, and the memory banks 20 formed in the semiconductor chip body 10.

In the present embodiment, the semiconductor chip body 10 has the memory banks 20 which include memory cells for storing data.

The memory banks 20 are located in the semiconductor chip body 10, for example, in the shape of a matrix. In the present embodiment, the memory banks 20 are located, for example, in the shape of a 2 by 2 matrix. Hereafter, the four memory banks 20, which are located in the semiconductor chip body 10, will be referred to as a first memory bank BK1, a second memory bank BK2, a third memory bank BK3, and a fourth memory bank BK4.

The first memory bank BK1 is located adjacent to the second memory bank BK2. The third memory bank BK3 is located opposite to the first memory bank BK1 and diagonally to the second memory bank BK2. The fourth memory bank BK4 is located adjacent to the third memory bank BK3, opposite to the second memory bank BK2, and diagonally to the first memory bank BK1.

In the present embodiment, the first through fourth memory banks BK1˜BK4 are spaced apart from each another on the semiconductor chip body 10 by predetermined distances.

The first pad group 30 is interposed between the first and third memory banks BK1 and BK3 and between the second and fourth memory banks BK2 and BK4. For example, the first pad group 30 is located at a position that is adjacent to the first and second memory banks BK1 and BK2.

The second pad group 40 is interposed between the first and third memory banks BK1 and BK3 and between the second and fourth memory banks BK2 and BK4. For example, the second pad group 40 is located at a position that is adjacent to the third and fourth memory banks BK3 and BK4.

The third pad groups 50 are interposed between the first and third memory banks BK1 and BK3 and between the second and fourth memory banks BK2 and BK4. More specifically, the third pad groups 50 are located between the first pad group 30 and the second pad group 40.

The first pad group 30, the second pad group 40 and the third pad groups 50 include their respective pads 32, 42 and 52. At least one third pad group 50 can be interposed between the first pad group 30 and the second pad group 40. In the present embodiment, two third pad groups 50 are interposed between the first pad group 30 and the second pad group 40 at both ends of the semiconductor chip body 10. Each of the third pad groups 50 includes, for example, one pad 52.

The pads 32 of the first pad group 30 and the pads 42 of the second pad group 40 are located along the X-axis as illustrated in FIG. 1. The pads 32 of the first pad group 30 and the pads 42 of the second pad group 40 can be located parallel to each other.

In the first embodiment of the present invention, where the third pad groups 50 are located between the first pad group 30 and the second pad group 40, the surface area of the semiconductor memory device 100 can be decreased as compared to the conventional art whose size is restrained from being decreased due to the location of pads.

For example, where the first pad group 30 and the second pad group 40 are located on the semiconductor chip body 10 without using the third pad groups 50, for example, a first number of pads are assigned to each of the first pad group 30 and the second pad group 40. For example, 18 pads (including the pads shown by dotted lines) are located in each of the first pad group 30 and the second pad group 40. Therefore, the semiconductor chip body 10 has a first length L1 along the X-axis when each of the first and second pad groups 30 and 40 include 18 pads as shown in FIG. 1.

On the contrary, in the first embodiment of the present invention, where the third pad groups 50 are located between the first pad group 30 and the second pad group 40 of the semiconductor chip body 10, a second number of pads that is less than the first number of pads, is assigned to each of the first pad group 30 and the second pad group 40.

In the first embodiment of the present invention, for example, only 17 pads are assigned to each of the first and second pad groups 30 and 40 since two pads 52 are assigned to the third pad groups 50. Accordingly, due to the fact that each of the first and second pad groups 30 and 40 has 17 pads, the semiconductor chip body 10 has a second length L2 along the X-axis that is less than the first length L1 where the third pad groups 50 are not used as shown in FIG. 1.

In the first embodiment, the pads 32 and 42 of the first and second pad groups 30 and 40 respectively, contact test probes (not shown) located parallel to the Y-axis, such that the electrical characteristics of the semiconductor memory device 100 can be tested. The pads 52 of the third pad groups 50 contact test probes (not shown) located parallel to the X-axis, such that the electrical characteristics of the semiconductor memory device 100 can be tested.

In the first embodiment of the present invention, as is apparent from the above description, the length of the semiconductor chip body, i.e., the length of the semiconductor memory device, can be decreased along the X-axis by including some of the pads that belong to the first and second pad groups 30 and 40 interposed between the adjoining memory banks, into the third pad groups 50 interposed between the first and second pad groups 30 and 40.

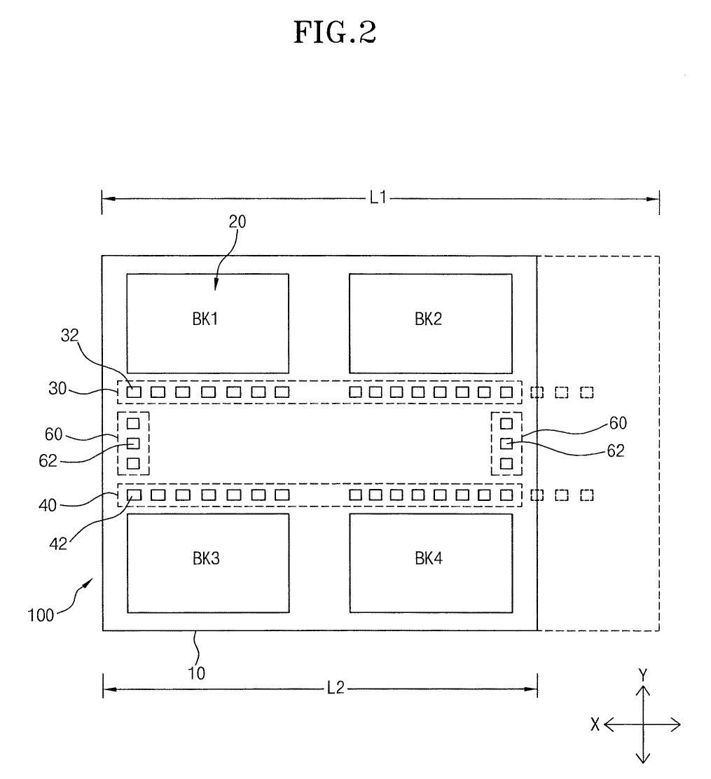

FIG. 2 is a plan view illustrating a semiconductor memory device in accordance with a second embodiment of the present invention. The semiconductor memory device according to the second embodiment of the present invention is substantially similar, except for the third pad group, to the aforementioned semiconductor memory device of the first embodiment. Therefore, a repeated description of the same component parts will be omitted herein. The same terms and reference numerals will be used to refer to the same component elements.

Referring to FIG. 2, a semiconductor memory device 100 includes a semiconductor chip body 10, memory banks 20, a first pad group 30, a second pad group 40, and third pad groups 60.

The first pad group 30 is interposed between the first and third memory banks BK1 and BK3 and between the second and fourth memory banks BK2 and BK4. For example, the first pad group 30 is located at a position which is adjacent to the first and second memory banks BK1 and BK2.

The second pad group 40 is interposed between the first and third memory banks BK1 and BK3 and between the second and fourth memory banks BK2 and BK4. For example, the second pad group 40 is located at a position which is adjacent to the third and fourth memory banks BK3 and BK4.

The third pad groups 60 are interposed between the first and third memory banks BK1 and BK3 and between the second and fourth memory banks BK2 and BK4. More specifically, the third pad groups 60 are located between the first pad group 30 and the second pad group 40.

The first pad group 30, the second pad group 40 and the third pad groups 60 include their respective pads 32, 42 and 62.

The pads 32 of the first pad group 30 and the pads 42 of the second pad group 40 are located along the X-axis as illustrated in FIG. 2. The pads 32 of the first pad group 30 and the pads 42 of the second pad group 40 can be located parallel to each other.

In the second embodiment of the present invention, at least one third pad group 60 can be interposed between the first and second pad groups 30 and 40. For example, two pad groups 60 are located between the first and second pad groups 30 and 40.

The pads 62 of each third pad group 60 are located, for example, along the Y-axis of FIG. 2. In the present embodiment, each third pad group 60 has three pads 62.

In the second embodiment of the present invention, where the third pad groups 60 each have a plurality of pads 62 located between the first pad group 30 and the second pad group 40, the surface area of the semiconductor memory device 100 can be decreased as compared to the conventional art whose size is restrained from being decreased due to the location of pads.

For example, where the first pad group 30 and the second pad group 40 are located on the semiconductor chip body 10 without using the third pad groups 60, for example, a first number of pads are assigned to each of the first pad group 30 and the second pad group 40. For example, 18 pads (including the three pads shown by dotted lines) are located in each of the first pad group 30 and the second pad group 40. Therefore, the semiconductor chip body 10 has a first length L1 along the X-axis when each of the first and second pad groups 30 and 40 include 18 pads as shown in FIG. 2.

On the contrary, in the second embodiment of the present invention, where the two third pad groups 60 each including three pads 62 are located between the first pad group 30 and the second pad group 40 of the semiconductor chip body 10, a second number of pads that is less than the first number of pads, is assigned to each of the first pad group 30 and the second pad group 40.

In the second embodiment of the present invention, for example, only 15 pads are assigned to each of the first and second pad groups 30 and 40 since three pads 62 are assigned to each of the two third pad groups 60. Accordingly, due to the fact that each of the first and second pad groups 30 and 40 has 15 pads, the semiconductor chip body 10 has a second length L2 along the X-axis that is less than the first length L1 where the third pad groups 60 are not used as shown in FIG. 2.

In the second embodiment of the present invention, the pads 32 and 42 of the first and second pad groups 30 and 40 respectively, contact test probes (not shown) located parallel to the Y-axis, such that the electrical characteristics of the semiconductor memory device 100 can be tested. The pads 62 of the third pad groups 60 contact test probes (not shown) located parallel to the X-axis, such that the electrical characteristics of the semiconductor memory device 100 can be tested.

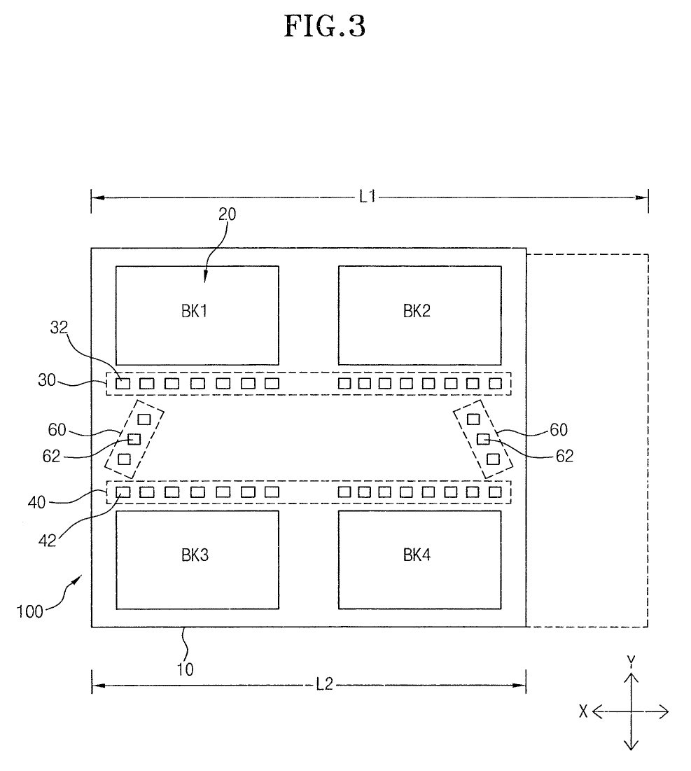

In the second embodiment of the present invention as illustrated, the pads 62 of the third pad groups 60 are located along the Y-axis that is orthogonal to the X-axis. However, unlike this, it can be envisaged that the pads 62 of the third pad groups 60 can be located obliquely located as shown in FIG. 3.

In the second embodiment of the present invention, as is apparent from the above description, the length of the semiconductor chip body, i.e., the length of the semiconductor memory device, can be decreased along the X-axis by including some of the pads that belong to the first and second pad groups 30 and 40 interposed between the adjoining memory banks, into the third pad groups 60 interposed between the first and second pad groups 30 and 40.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor memory device comprising:
memory banks having memory cells and the memory banks being located in a matrix pattern;
a first pad group having first pads that are arranged in a line between two adjoining memory banks;
a second pad group having second pads that are arranged in a line between the two adjoining memory banks; and
at least one third pad group interposed between the first and second pad groups and having at least one third pad.

2. The semiconductor memory device according to claim 1, wherein the second pads of the second pad group are parallel to the first pad group arranged in a line.

3. The semiconductor memory device according to claim 1, wherein the memory banks include a first memory bank, a second memory bank that is adjacently located to the first memory bank, a third memory bank that is adjacently located to the first memory bank and diagonally with respect to the second memory bank, and a fourth memory bank that is adjacently located to the second memory bank and diagonally with respect to the first memory bank.

4. The semiconductor memory device according to claim 3, wherein the first and second pad groups are interposed between the first and third memory banks and between the second and fourth memory banks.

5. The semiconductor memory device according to claim 3, wherein the third pad group is interposed between the first and third memory banks and/or between the second and fourth memory banks.

6. The semiconductor memory device according to claim 1, wherein a number of first pads of the first pad group and a number of second pads of the second pad group is the same.

7. The semiconductor memory device according to claim 1, wherein a number of first pads of the first pad group is different from a number of second pads of the second pad group.

8. The semiconductor memory device according to claim 1, wherein a plurality of third pads are located between the first and second pad groups in a matrix pattern.

9. The semiconductor memory device according to claim 8, wherein the third pads are arranged in a line having a direction that is different from a pad arrangement direction of the first and second pad groups.

10. The semiconductor memory device according to claim 9, wherein the third pads are arranged in a direction that is perpendicular to the pad arrangement direction of the first and second pad groups.

11. The semiconductor memory device according to claim 9, wherein the third pads are arranged in an oblique direction with respect to the pad arrangement direction of the first and second pad groups.
